(19) United States
(12) Patent Application Publication
(10) Pub. No.: US 2009/0068784 A1
(43) Pub. Date: Mar. 12, 2009

(54) Method for Manufacturing of the Image Sensor

(76) Inventor: SEOUNG HYUN KIM, Pocheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/205,026

(22) Filed: Sep. 5, 2008

(30) Foreign Application Priority Data
Sep. 10, 2007 (KR) 10-2007-0091338

(51) Int. Cl. H01L 31/18

(52) U.S. Cl. 438/70; 257/E31.127

(57) ABSTRACT

Methods for manufacturing an image sensor are provided. A semiconductor substrate having a transistor can be prepared, and a proton layer can be formed in the substrate. A hydrogen gas layer can be formed by performing a heat treatment process on the semiconductor substrate, and a bottom portion of the semiconductor substrate defined by the hydrogen gas layer can be removed.

### CROSS-REFERENCE TO RELATED APPLICATION

The present application claims the benefit under 35 U.S.C. §119 of Korean Patent Application No. 10-2007-0091338, filed Sep. 10, 2007, which is hereby incorporated by reference in its entirety.

### BACKGROUND

An image sensor is a semiconductor device that converts an optical image into an electrical signal. Image sensors are typically classified as charge coupled devices (CCD) or complementary metal oxide semiconductor (CMOS) image sensors (CIS).

A CMOS image sensor generally includes a photodiode and a MOS transistor in each unit pixel to sequentially detect an electrical signal in a switching manner, thereby forming an image.

### BRIEF SUMMARY

Embodiments of the present invention provide improved methods for manufacturing an image sensor.

In an embodiment, a method for manufacturing an image sensor can comprise: preparing a semiconductor substrate comprising a transistor; forming a proton layer on the semiconductor substrate; forming a hydrogen gas layer by performing a heat treatment process on the semiconductor substrate including the proton layer; and removing a bottom portion of the semiconductor substrate. The bottom portion of the semiconductor substrate can include the hydrogen gas layer.

### BRIEF DESCRIPTION OF THE DRAWINGS

FIGS. 1 to 10 are cross-sectional views of a method for manufacturing an image sensor according to an embodiment of the present invention.

### DETAILED DESCRIPTION

When the terms “on” or “over” or “above” are used herein, when referring to layers, regions, patterns, or structures, it is understood that the layer, region, pattern, or structure can be directly on another layer or structure, or intervening layers, regions, patterns, or structures may also be present, When the terms “under” or “below” are used herein, when referring to layers, regions, patterns, or structures, it is understood that the layer, region, pattern, or structure can be directly under the other layer or structure, or intervening layers, regions, patterns, or structures may also be present.

Hereinafter, methods for manufacturing an image sensor according to embodiments of the present invention will be described in detail with reference to the accompanying drawings.

The description of the present invention includes reference to a complementary metal oxide semiconductor (CMOS) image sensor (CIS). However, embodiments of the present invention are not limited thereto. For example, methods of the present invention can be applied to any suitable image sensor known in the art, such as a charge coupled device (CCD) image sensor.

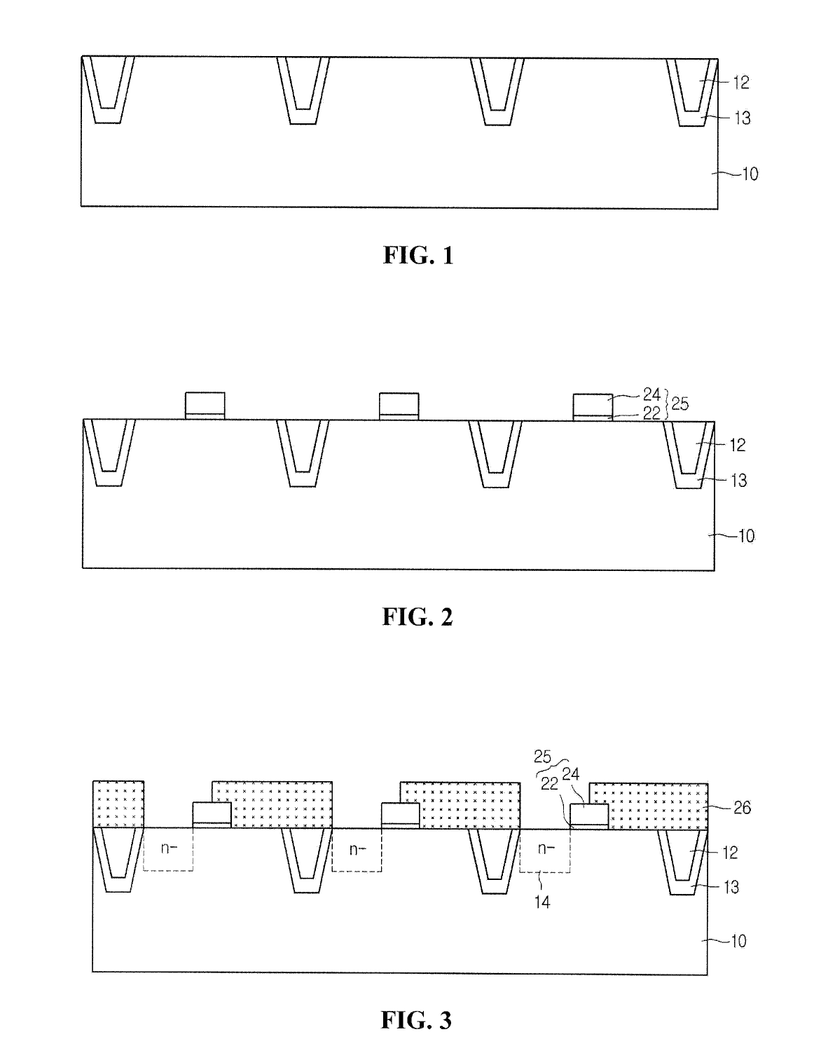

FIGS. 1 to 10 are cross-sectional views of a method for manufacturing an image sensor according to an embodiment of the present invention.

Referring to FIG. 1, a device isolating layer 12 can be formed in a semiconductor substrate 10. The semiconductor substrate 10 can be any suitable substrate known in the art. For example, the semiconductor substrate 10 can be a high concentration p-type (p++) silicon substrate.

In an embodiment, a low-concentration p-type epi layer (not shown) can be formed on the semiconductor substrate 10 with the device isolating layer 12 formed in the epi layer. The p-type epi layer (not shown) can help make a depletion region of a photodiode large and deep so that the ability of the photodiode for collecting photo charges can be enhanced. Also, if a p-type epi layer is formed in a p++ semiconductor substrate, charges can recombine before diffusing to neighboring unit pixel, thereby r educing random diffusion of photo charges and making it possible to reduce a change in a transfer function of photo charges.

The device isolating layer 12 can be formed by any suitable method known in the art. In an embodiment, forming the device isolating layer 12 can include forming a trench in the semiconductor substrate 10, forming a channel stop ion implantation region 13 around the trench by implanting ions into the trench, and forming an insulating material in the trench.

The channel stop ion implantation region 13 can help inhibit cross talk or leakage current between adjacent pixels.

Referring to FIG. 2, a gate 25 can be formed on the semiconductor substrate 10. The gate 25 can include a gate oxide film 22 and a gate electrode 24. In an embodiment, the gate 25 can be formed by forming a gate oxide layer (not shown) on the semiconductor substrate 10, forming a gate electrode layer (not shown) on the gate oxide layer, and then patterning the gate oxide layer and the gate electrode layer to form the gate 25.

The gate oxide film 22 can be formed of any suitable material known in the art, for example, an oxide film. Additionally, the gate electrode 24 can be formed of any suitable material known in the art, for example, a polysilicon layer or a metal silicide layer.

Referring to FIG. 3, a first photoresist pattern 26 can be formed on the semiconductor substrate 10 and the gate 25, exposing a side of the gate 25. A first ion implantation layer 14 can be formed by performing a first ion implantation process using the first photoresist pattern 26 as an ion implantation mask.

In an embodiment, the first ion implantation layer 14 can be formed by implanting n-type impurities.

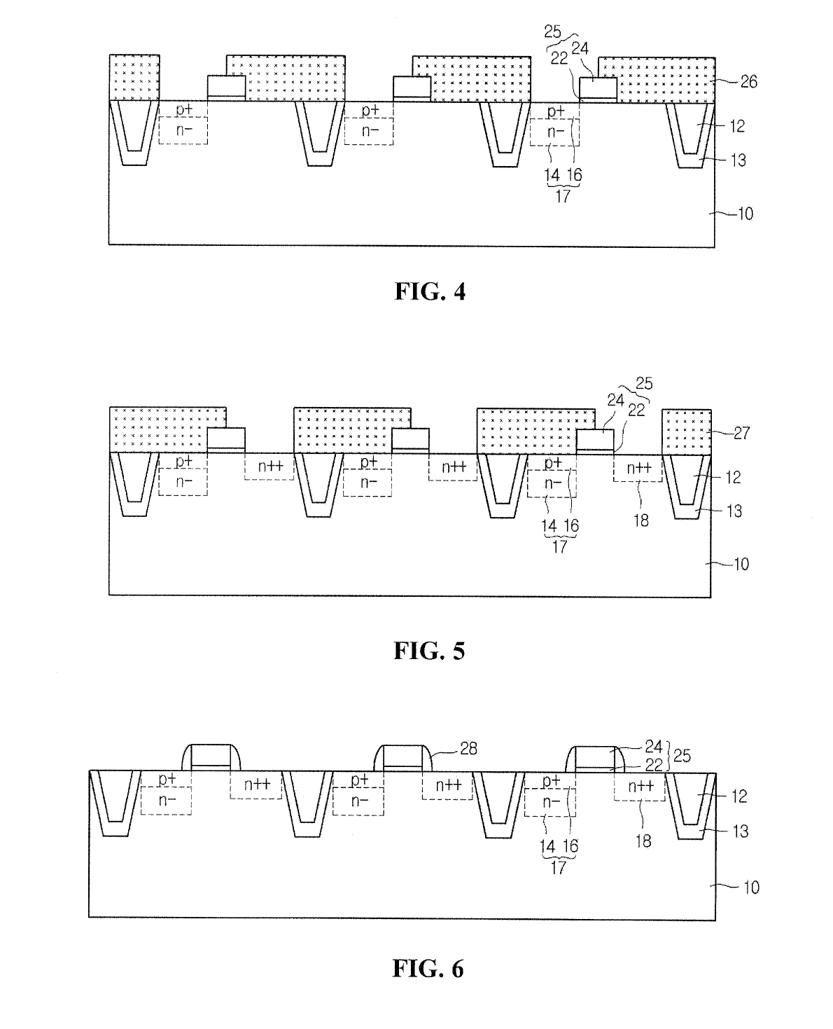

Referring to FIG. 4, a second ion implantation layer 16 can be formed by performing a second ion implantation process using the first photoresist pattern 26 as an ion implantation mask.

In an embodiment, the second ion implantation layer 16 can be formed by implanting p-type impurities. Accordingly, a P-N junction region 17 can be formed by the first ion implantation layer 14 and the second ion implantation layer 16.

In certain embodiments, a PNP photodiode can be provided by the P-N junction region 17 and the semiconductor substrate 10. In these embodiments, the semiconductor substrate 10 can be a p-type substrate.

Referring to FIG. 5, the first photoresist pattern 26 can be removed, and a second photoresist pattern 27 can be formed on the semiconductor substrate 10 and the gate 25, exposing a side of the gate 25 opposite from the side in which the first and second ion implantation layers 14 and 16 were formed. A third ion implantation layer 18 can be formed by performing a third ion implantation process using the second photoresist pattern 27 as an ion implantation mask. The third ion implantation layer 18 can function as a floating diffusion region

In an embodiment, the third ion implantation layer 18 can be formed by implanting n-type impurities at a high concentration.

During operation of the image sensor photo charges generated in the P-N junction region 17 can be transferred to the third ion implantation layer 18, and photo charges transferred to the third ion implantation layer 18 can be transferred to a circuitry unit (not shown).

Referring to FIG. 6, a spacer 28 can be formed on a side wall of the gate 25.

The spacer 28 can be formed by any suitable process known in the art. In an embodiment, an oxide layer, a nitride layer, and an oxide layer can be sequentially formed on the semiconductor substrate 10 to form an oxide-nitride-oxide (ONO) layer. An etching process can be performed on the ONO layer to form the spacer 28. In an alternative embodiment, an oxide-nitride (ON) layer can be formed and etched to form the spacer 28.

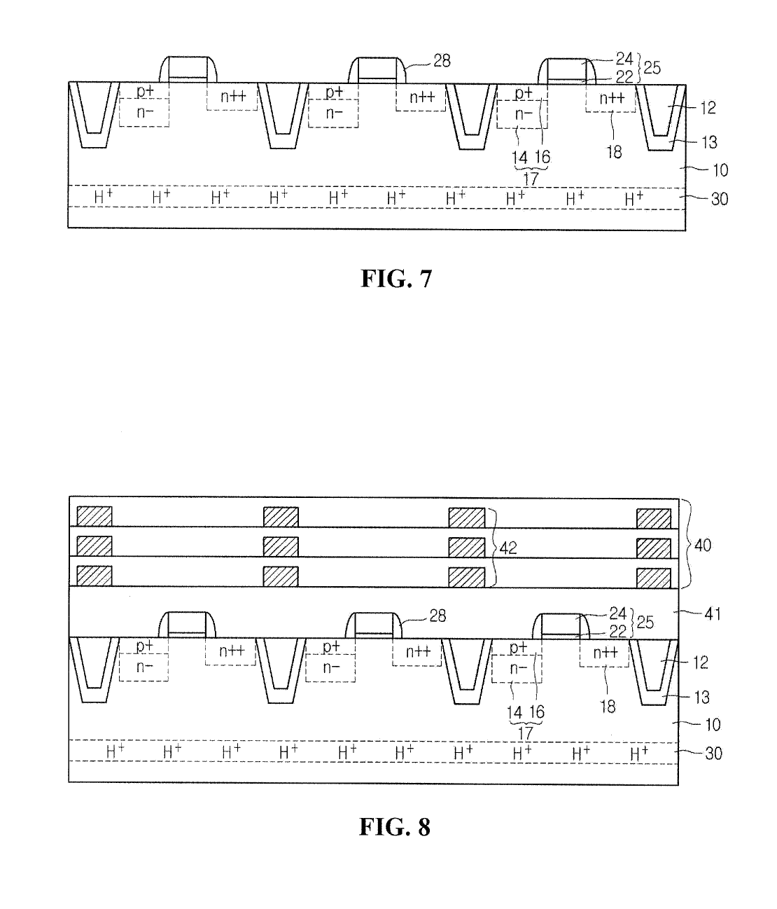

Referring to FIG. 7, a proton layer 30 can be formed in the semiconductor substrate 10, by performing a fourth ion implantation process.

The fourth ion implantation process can be performed using protons (H⁺).

The depth of the proton layer 30 can be controlled by the ion implantation energy used during the fourth ion implantation process.

Referring to FIG. 8, a premetal dielectric (PMD) 41 can be formed on the semiconductor substrate 10 including the gate 25 and the first, second, and third ion implantation layers 14, 16, and 18. A metal wiring layer 40 including a wiring 42 can be formed on the premetal dielectric 41.

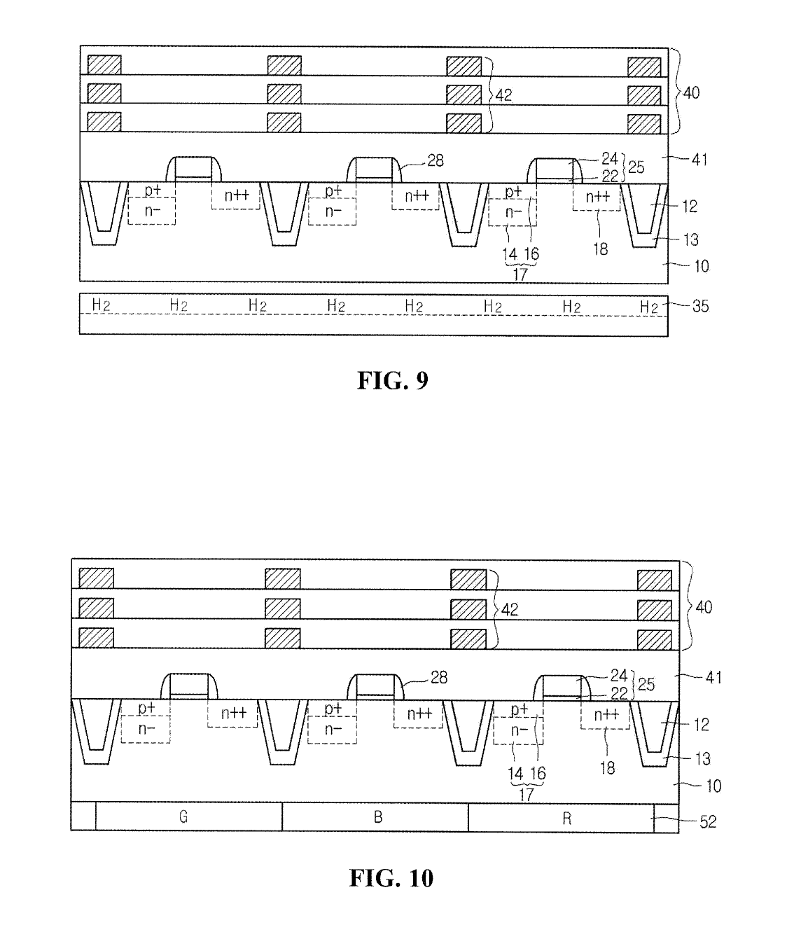

Referring to FIG. 9, a hydrogen gas (H₂) layer 35 can be formed by performing a heat treatment process on the semiconductor substrate 10.

The proton layer 30 can be converted into the hydrogen gas layer 35 by performing the heat treatment process on the semiconductor substrate 10.

At this time, the proton layer 30 can be converted into the hydrogen gas layer 35, thereby making it possible to separate a bottom portion of the semiconductor substrate 10. The bottom portion of the semiconductor substrate 10 can include at least a portion of the hydrogen gas layer 35. In an embodiment, the bottom portion of the semiconductor substrate 10 can include at least a majority of the hydrogen gas layer 35. In a further embodiment, the bottom portion of the semiconductor substrate 10 can include approximately all of the hydrogen gas layer 35. In yet a further embodiment, the bottom portion of the semiconductor substrate can include the entire hydrogen gas layer 35.

The thickness of the separated portion of the semiconductor substrate 10 can be controlled according to the formation depth of the proton layer 30, which can be controlled by the ion implantation energy used during the fourth ion implantation process.

That is, the thickness of the bottom portion of the semiconductor substrate 10 that can be separated can be controlled by the ion implantation energy used during the fourth ion implantation process.

Referring FIG. 10, a color filter array 52 can be formed on the backside of the semiconductor substrate 10.

The color filter array 52 can be formed in a region corresponding to a unit pixel of a light-receiving area. The color filter array 52 can be formed by forming a color filter layer (not shown) and patterning the color filter layer.

Since the color filter array 52 can be formed on the backside of the semiconductor substrate 10 light can enter from below the photodiode 17 in the semiconductor substrate 10.

Although not shown, in an embodiment, a mircolens and a microlens protective layer for protecting the microlens can be formed on or under the color filter array 52.

According to embodiments of the present invention, a bottom, or backside, portion of the semiconductor substrate 10 can be separated and removed, making it possible to improve the sensitivity of the image sensor.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing an image sensor, comprising:
preparing a semiconductor substrate comprising a transistor;
forming a proton layer in the semiconductor substrate;
forming a hydrogen gas layer by performing a heat treatment process with respect to the semiconductor substrate including the proton layer; and
removing a bottom portion of the semiconductor substrate, wherein the bottom portion comprises at least a portion of the hydrogen gas layer.

2. The method according to claim 1, further comprising:
forming a color filter array on a backside of the semiconductor substrate after removing the bottom portion of the semiconductor substrate.

3. The method according to claim 2, wherein preparing the semiconductor substrate comprises forming a photodiode in the substrate at a side of the transistor, wherein a color filter of the color filter array is formed to correspond to the photodiode.

4. The method according to claim 2, further comprising forming a microlens on the backside of the semiconductor substrate after removing the bottom portion of the semiconductor substrate.

5. The method according to claim 4, further comprising forming a protective layer for protecting the microlens on the backside of the semiconductor substrate after removing the bottom portion of the semiconductor substrate.

6. The method according to claim 1, wherein preparing the semiconductor substrate comprises:
forming a device isolating layer in the semiconductor substrate;
forming a gate on the semiconductor substrate;
forming a P-N junction region in the semiconductor substrate at a first side of the gate; and
forming a diffusion region in the semiconductor substrate at a second side of the gate.

7. The method according to claim 6, wherein forming the device isolating layer comprises:
forming a trench in the semiconductor substrate; and
depositing an insulating material in the trench.

8. The method according to claim 7, further comprising forming a channel stop ion implantation region by implanting ions in the trench before depositing the insulating material in the trench.

9. The method according to claim 1, wherein performing the heat treatment process converts at least a portion of the proton layer into the hydrogen gas layer.

10. The method according to claim 1, further comprising forming a metal wiring layer on the semiconductor substrate.

11. The method according to claim 1, wherein forming the proton layer comprises performing an ion implantation process on the semiconductor substrate.

12. The method according to claim 11, wherein performing the ion implantation process comprises implanting protons into the semiconductor substrate.

13. The method according to claim 11, wherein a depth of the proton layer in the semiconductor substrate is controlled by an ion implantation energy used during the ion implantation process.

14. The method according to claim 1, wherein the bottom portion of the semiconductor substrate comprises at least a majority of the hydrogen gas layer.

15. The method according to claim 1, wherein the bottom portion of the semiconductor substrate comprises approximately all of the hydrogen gas layer.

16. The method according to claim 1, wherein the bottom portion of the semiconductor substrate comprises the hydrogen gas layer.
